(19) United States
(12) Patent Application Publication
(10) Pub. No.: US 2026/0271781 A1
(43) Pub. Date: Sep. 10, 2026

(54) OPTIMAL MEMORY CONFIGURATIONS IN A SILICON INTERPOSER FOR HIGH-SPEED DRAM

(71) Applicant: XILINX, INC., San Jose, CA (US)

(72) Inventors: Jinsung YOUN, San Jose, CA (US); Young Soo LEE, Santa Clara, CA (US); Joungwook MOON, San Jose, CA (US); Hong SHI, Los Gatos, CA (US)

(21) Appl. No.: 19/072,733

(22) Filed: Mar. 6, 2025

(51) Int. Cl. H10W 90/00

(52) U.S. Cl. CPC H10W 90/00; H10W 90/724; H10W 90/754

(57) ABSTRACT

The examples describe a chip package including an interposer including at least one embedded deep trench capacitor (eDTC) and at least one of an inductor, a T-coil, or a combination thereof and logic chips electrically connected to the interposer. The at least one eDTC is disposed in a different material layer of the interposer than the at least one of the inductor, the T-coil, or the combination thereof. The at least one of the inductor, the T-coil, or the combination thereof are disposed within a keep-out zone (KOZ). The at least one of the inductor, the T-coil, or the combination thereof are disposed in an upper layer of the interposer.

### TECHNICAL FIELD

Examples of the present disclosure generally relate to semiconductor packaging technology, and, in particular, to optimal memory configurations in a silicon interposer for high-speed dynamic random access memory (DRAM).

### BACKGROUND

The evolution of semiconductor packaging technologies has led to significant advancements in 2.5D integration, particularly with the use of silicon (Si) interposers. Unlike traditional 2D packaging, which places components flat on a single plane, 2.5D packaging introduces a vertical dimension, allowing for the placement of multiple chip components on a shared Si interposer. The Si interposer acts as a high-density interconnection layer that connects the chips, enabling communication between them through microbumps or through-silicon vias (TSVs). By integrating components like logic chips, memory, and even analog components in a compact form, 2.5D technology offers substantial benefits, including improved performance, reduced power consumption, and enhanced signal integrity.

The Si interposer provides a low-resistance, high-performance electrical pathway for data transmission between chips, while also serving as a thermal management solution. As the demand for higher processing power in smaller form factors increases, Si interposers offer an efficient way to meet these needs without compromising on performance. By facilitating high-speed communication between components, Si interposers allow for better bandwidth utilization, making them ideal for applications in high-performance computing, graphics processing, and memory systems.

### SUMMARY

One example described herein is a chip package including an interposer including at least one embedded deep trench capacitor (eDTC) and at least one of an inductor, a T-coil, or a combination thereof and logic chips electrically connected to the interposer.

One example described herein is a chip package including an interposer including at least one of an inductor, a T-coil, or a combination thereof disposed in a keep-out zone (KOZ) in an upper region of the interposer and logic chips electrically connected to the interposer.

One example described herein is a method including forming at least one embedded deep trench capacitor (eDTC) and at least one of an inductor, a T-coil, or a combination thereof in an interposer and electrically connecting logic chips to the interposer, where the logic chips include data in/out (DQ) blocks.

### BRIEF DESCRIPTION OF DRAWINGS

So that the manner in which the above recited features can be understood in detail, a more particular description, briefly summarized above, may be had by reference to example implementations, some of which are illustrated in the appended drawings. It is to be noted, however, that the appended drawings illustrate only typical example implementations and are therefore not to be considered limiting of its scope.

FIG. 1A illustrates a cross-sectional view of advanced packing technology with a chip-on-wafer-on-substrate (CoWoS) structure, according to an example.

FIG. 1B illustrates a cross-sectional view of advanced packing technology with a system-on-integrated-chips (SoIC) structure, according to an example.

FIG. 2 is a cross-sectional view of a memory configuration for the advanced packing technology including inductors and/or T-coils in the silicon interposer, according to an example.

FIG. 3A illustrates a first memory configuration where two data in/out (DQ) blocks share one embedded deep trench capacitor (eDTC), according to an example.

FIG. 3B illustrates a second memory configuration where four DQ blocks share one eDTC, according to an example.

FIGS. 3C-3F are inductor coil designs, according to an example.

FIG. 3G illustrates different inductor configurations used in the dies and in the interposer, according to an example.

FIG. 4 illustrates a method for providing an optimized memory configuration in a silicon (Si) interposer, according to an example.

FIG. 5 is a block diagram of an accelerator unit (AU) configured to execute workloads for applications running on a processing system, according to an example.

To facilitate understanding, identical reference numerals have been used, where possible, to designate identical elements that are common to the figures. It is contemplated that elements of one example may be beneficially incorporated in other examples.

### DETAILED DESCRIPTION

Various features are described hereinafter with reference to the figures. It should be noted that the figures may or may not be drawn to scale and that the elements of similar structures or functions are represented by like reference numerals throughout the figures. It should be noted that the figures are only intended to facilitate the description of the features. They are not intended as an exhaustive description of the examples herein or as a limitation on the scope of the claims. In addition, an illustrated example need not have all the aspects or advantages shown. An aspect or an advantage described in conjunction with a particular example is not necessarily limited to that example and can be practiced in any other examples even if not so illustrated, or if not so explicitly described.

The semiconductor industry has experienced a drive toward miniaturization and enhanced performance, necessitating innovative packaging technologies to meet the demands of modern electronic devices. Traditional 2D packaging approaches, while effective for certain applications, face challenges in scaling to meet the power, performance, and area (PPA) requirements of advanced systems. In response to these limitations, 2.5D packaging technology has emerged as a solution. By using silicon (Si) interposers to interconnect multiple dies within a single package, 2.5D technology achieves higher integration density, improved thermal performance, and enhanced signal integrity, making it a better choice for high-performance computing and artificial intelligence (AI) applications.

In 2.5D packaging, the Si interposer is positioned between the logic chips and the package substrate, acting as a bridge that facilitates seamless communication and power delivery across the system. This configuration is advantageous for integrating high-speed dynamic random access memory (DRAM) with logic dies, where the Si interposer provides the necessary bandwidth and minimizes latency. The high-density interconnections enabled by the Si interposer eliminate the bottlenecks encountered with traditional substrates, ensuring robust performance in data-intensive applications.

The Si interposer provides a platform for high-density interconnections between dies. Unlike conventional organic substrates, Si interposers offer superior mechanical stability and support finer interconnect pitches, enabling closer integration of heterogeneous components, such as logic, memory, and analog dies. This capability not only enhances electrical performance by reducing parasitics but also enables shorter signal paths, which significantly improve bandwidth and energy efficiency.

One of the primary applications of 2.5D packaging is in the integration of high-speed DRAM to complement high-performance logic dies. The silicon interposer’s ability to handle dense interconnects and deliver high bandwidth is beneficial for memory-intensive workloads, such as those found in AI training. By enabling direct communication between the logic and memory components, the Si interposer minimizes signal degradation and ensures reliable operation under demanding conditions.

Despite its advantages, 2.5D packaging technology introduces challenges, including the complexity of interposer fabrication and thermal management. Si interposers, while providing high precision and performance, come with higher manufacturing costs and design considerations compared to traditional substrates. Additionally, the integration of high-speed DRAM with logic dies necessitates advanced thermal management strategies to prevent overheating and maintain system reliability. Moreover, achieving high-speed operation of more than 10Gb/s per pin while maintaining high power noise immunity may be challenging for current Si interposers. High-speed operation of more than 10 Gbps per pin presents design challenges in signal integrity, power delivery, thermal management, and interconnect technologies.

For example, at a high-speed operation of more than 10Gb/s per pin, maintaining clean, undistorted signals is paramount due to reduced noise margins and increased sensitivity to interference. Reliable power delivery is also paramount for maintaining stable operation at a high-speed operation of greater than 10 Gbps per pin.

In view of such challenges, the examples present a method and system for achieving high-speed operation of more than 10Gb/s per pin while maintaining high power noise immunity. The examples use inductors and/or T-coils to extend bandwidth for high-speed operation and integrate an embedded deep trench capacitor (eDTC) formed in the Si interposer to filter out power noises like simultaneous switching noise (SSN) and simultaneous switching output (SSO). The examples further deliver optimal inductor/T-coil and eDTC placement to achieve better signal and power integrity by saving layout area.

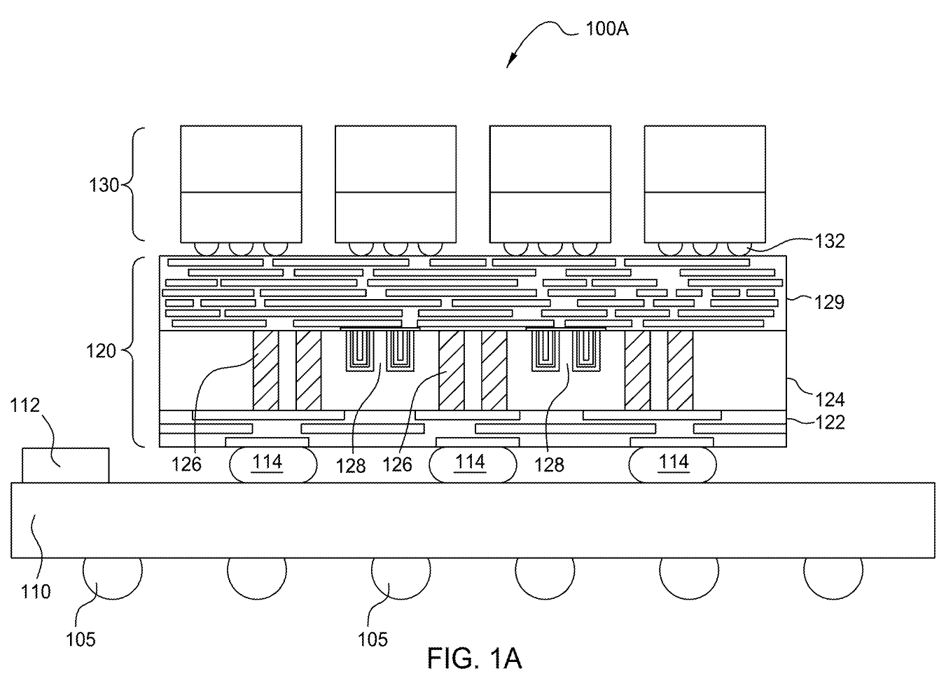

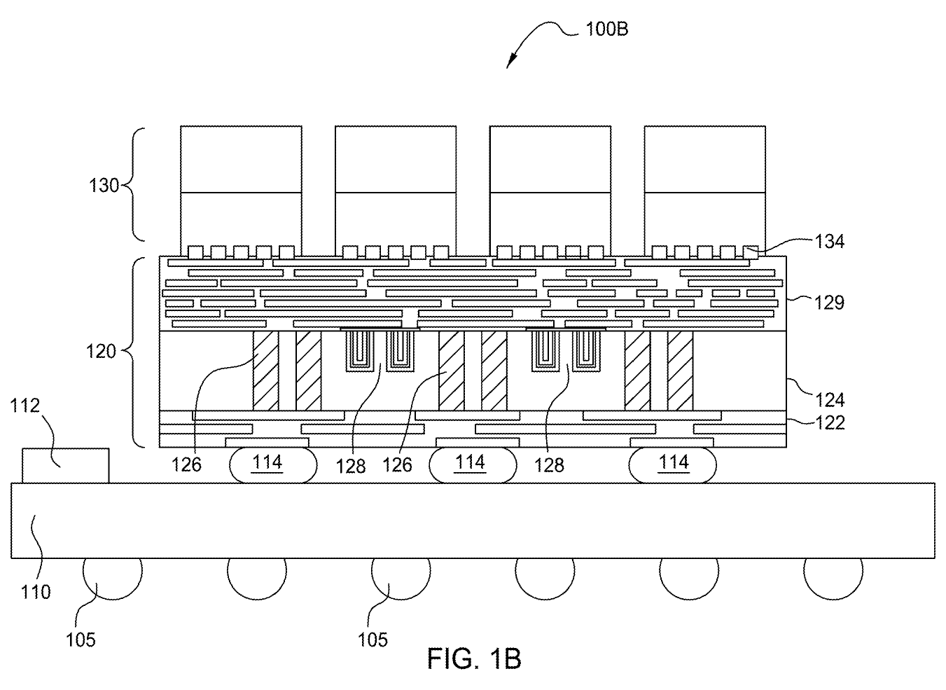

FIG. 1A illustrates a cross-sectional view of advanced packing technology with a chip-on-wafer-on-substrate (CoWoS) structure, according to an example.

The cross-sectional view of structure 100A shows a Si interposer 120 positioned between a package substrate 110 and logic chips 130. The structure 100A may be referred to as a chip-on-wafer-on-substrate (CoWoS) structure. The structure 100A may be referred to as a chip package or semiconductor package assembly or semiconductor chip device.

The package substrate 110 rests on a ball grid array (BGA) 105. Conductive bumps 114 are formed directly between the package substrate 110 and the Si interposer 120. The conductive bumps 114 may be referred to as flip chip bumps. Additionally, on-package decoupling (OPD) 112 may be present on the package substrate 110. The OPD 112 may include integrating small capacitors directly onto the package substrate 110 to provide a local source of power and mitigate voltage fluctuations caused by rapidly changing current demands within the chip.

The Si interposer 120 formed over the package substrate 110 may include a backside redistribution layer (RDL) 122, an interposer layer 124, and a metal routing layer 129. The RDL 122 provides for fine-pitch wiring and is made from, e.g., copper or aluminum. The RDL 122 supports the conductive bumps 114 for chip-to-interposer connections. The interposer layer 124 includes through-silicon-vias (TSVs) 126 and embedded deep trench capacitors (eDTCs) 128. The TSVs 126 provide vertical connectivity through the Si interposer 120. In other words, the TSVs 126 enable electrical signals to pass between the top and bottom layers. TSVs 126 may include copper or tungsten. The eDTC 128 is a high-density capacitor that is formed by etching deep trenches into the Si and then using the trenches to create high-capacitance structures. Placing the eDTC 128 directly in the Si interposer 120 minimizes inductive and resistive losses, and reduces power noise. In one example, multiple eDTCs 128 may be formed within the Si interposer 120. The eDTCs 128 may be formed between the TSVs 126. A plurality of metal layers may be formed over the interposer layer 124. The plurality of metal layers may be collectively referred to as a metal routing layer 129. The metal routing layer 129 enables communication with the logic chips 130. The logic chips 130 may be referred to as dies or integrated circuits (ICs) or simply chips. The Si interposer 120 is electrically connected to the logic chips 130 via, e.g., microbumps 132. The microbumps 132 can reach of a pitch between about 30um and 50um.

The Si interposer 120 in high-speed DRAM systems ensures the efficient operation of memory modules. The Si interposer 120 addresses power noise and maintains high power noise immunity. Power noise immunity refers to the ability of a system to operate reliably despite variations or disturbances in the power supply voltage, such as noise, ripple, or transients. In high-speed systems, especially those running at more than 10 Gbps per pin, maintaining proper power noise immunity is beneficial to ensure signal integrity, low bit error rates (BER), and stable operation. Sources of power noise include at least simultaneous switching noise (SSN), power supply ripple, crosstalk, and electromagnetic interference (EMI).

Regarding the reduction of power noise, the Si interposer 120 integrates a highly controlled power delivery network (PDN), minimizing impedance variations. Its planar structure supports low-inductance connections, reducing voltage ripple and noise. Built-in decoupling capacitors in the Si interposer 120 close to the DRAM die stabilize the power supply, absorbing transients and suppressing noise. The Si interposer 120 minimizes signal propagation delays and EMI by shortening the distance between DRAM dies and the host processor. Regarding high power noise immunity, Si interposers 120 are fabricated using high-precision techniques, ensuring uniform impedance across traces and minimizing hotspots that may intensify noise. The use of differential signaling and advanced routing techniques in the Si interposer 120 reduces susceptibility to power noise. Heat dissipation features in the Si interposer 120 prevent thermal-induced noise, which can degrade signal quality. Further, the Si interposer's 120 design isolates power planes and sensitive signal lines, ensuring high noise immunity even under fluctuating load conditions.

At speeds exceeding 10 Gbps per pin, systems face tighter noise margins and higher sensitivity to power noise because of narrow voltage margins, higher switching frequencies, smaller rise and fall times, and increased power density. In other words, signal swings are smaller, making even small noise levels significant, faster data rates result in more simultaneous switching events increasing SSN, faster transitions increase high-frequency noise components, and high-speed operations demand more power within a smaller area.

One approach to improving power delivery involves integrating eDTCs 128 into the Si interposer 120. These capacitors, working in conjunction with on-die decoupling capacitors in logic chips and external capacitors like on-package decoupling (e.g., the OPD 112) and land-side capacitors, form a multi-tiered decoupling strategy that significantly reduces power noise and enhances power noise immunity. eDTCs 128 are embedded into the Si interposer 120 to provide a high-density and low-impedance local decoupling solution. These capacitors store charge close to the load, minimizing voltage fluctuations caused by rapid changes in current demand, such as those seen during simultaneous switching. By embedding these capacitors in the Si interposer 120, the eDTCs 128 can operate with reduced parasitic inductance compared to traditional discrete capacitors, which are placed further away in the package hierarchy. This proximity to high-speed logic and DRAM chips makes eDTCs highly effective at mitigating power noise, particularly at high frequencies where noise immunity is critical.

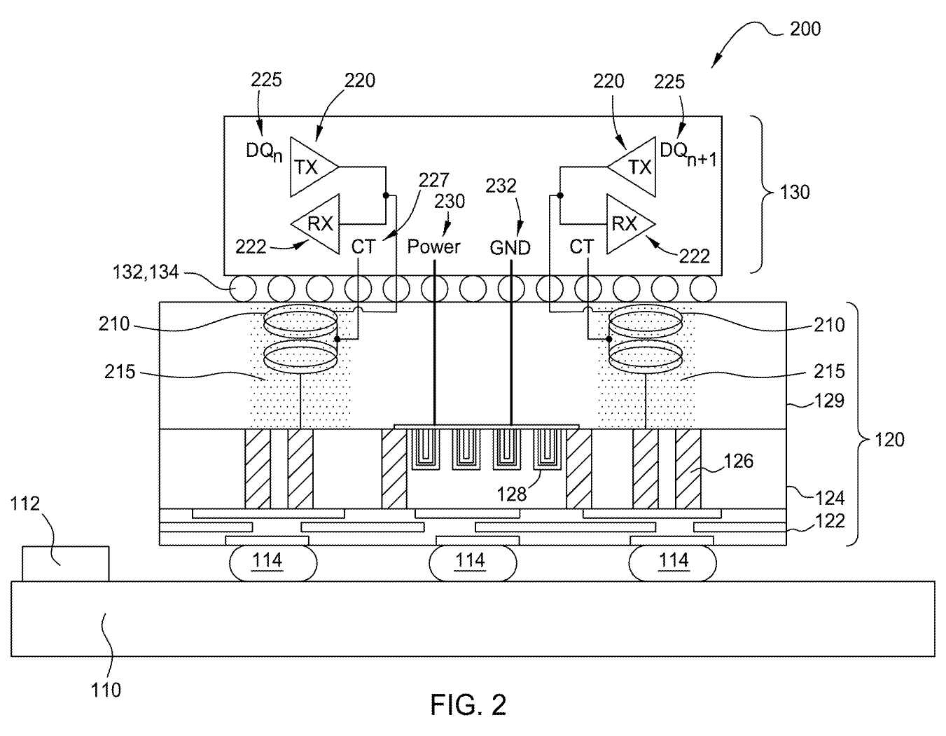

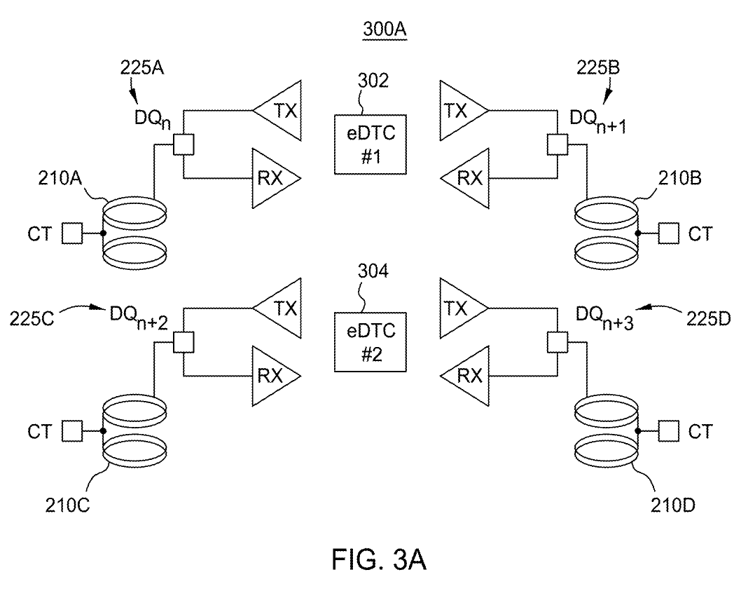

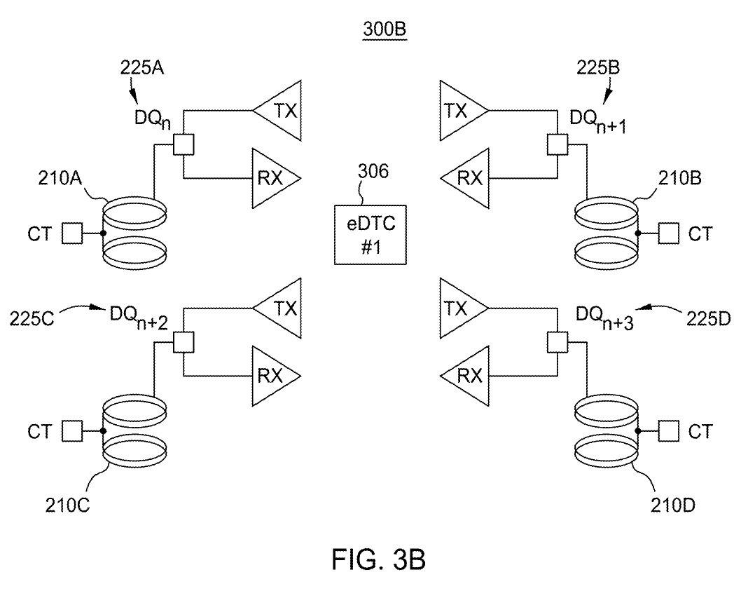

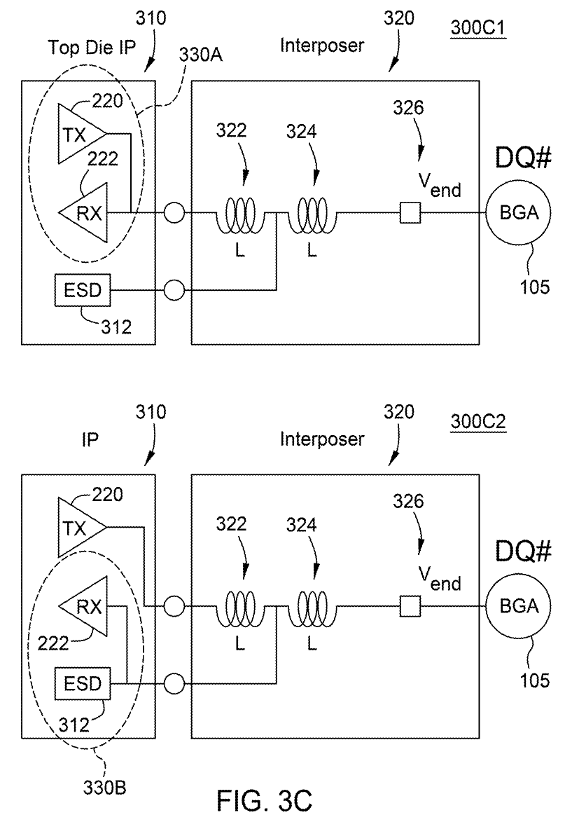

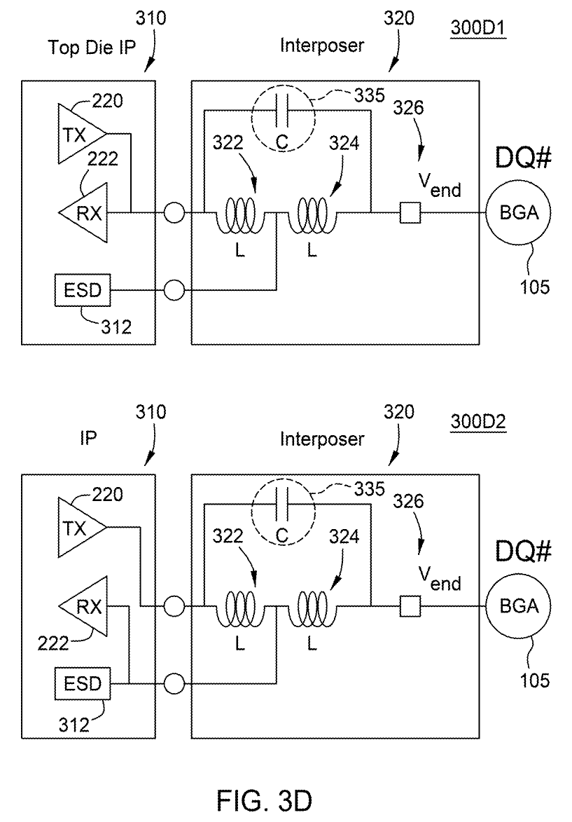

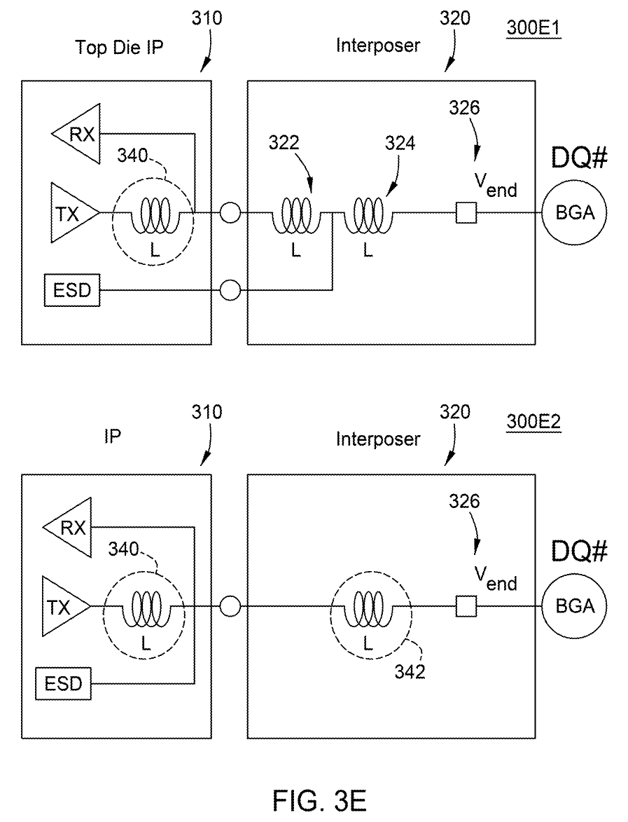

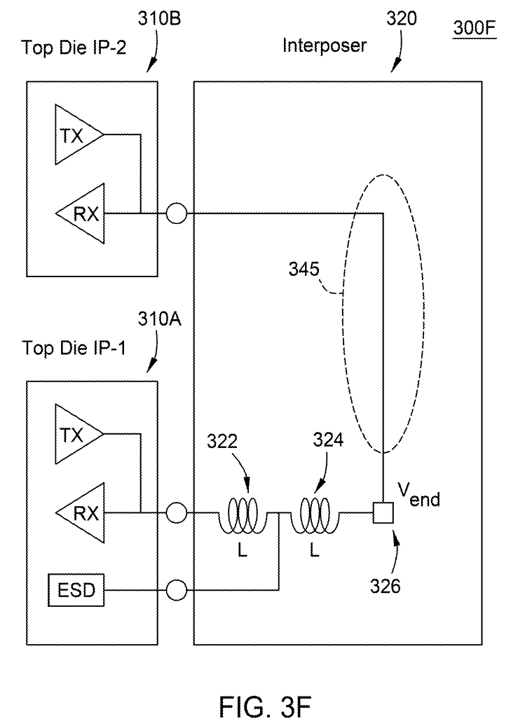

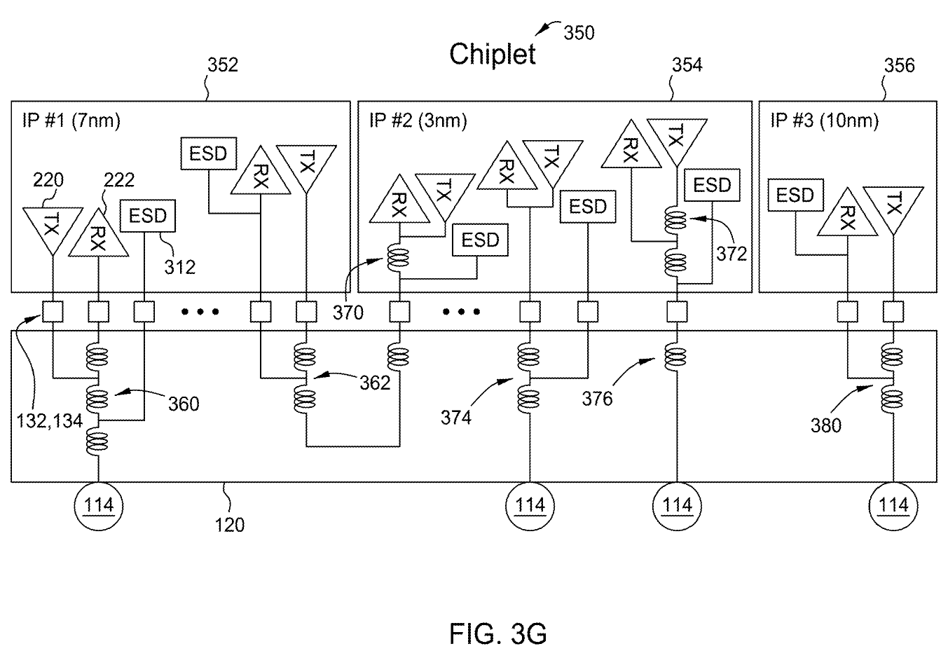

Therefore, from a power integrity perspective, the eDTC 128 in the Si interposer 120 can help reduce power noises along with an on-die decoupling capacitor in the logic chips 130, as well as the OPD 112 and/or a land-side capacitor (LSC). However, the layout area for eDTC 128 needs to be optimized to meet keep-out zones (KOZs) from other intellectual property (IP), components, and density rules. As such, the examples focus on optimal eDTC placement by considering signal integrity as well. This further involves incorporating inductors and/or T-coils in the Si interposer 120, as described below with reference to FIG. 2. The examples employ inductors and/or T-coils to extend bandwidth for high-speed operation and integrate an eDTC formed in the Si interposer to filter out power noises like SSN and SSO. The examples further deliver optimal inductor/T-coil and eDTC placement to achieve better signal and power integrity by saving layout area, as described below with reference to FIGS. 3A-3B.

FIG. 1B illustrates a cross-sectional view of advanced packing technology with a system-on-integrated-chips (SoIC) structure, according to an example.

FIG. 1B is similar to FIG. 1A and, as such, a description of similar elements will be omitted for clarity and conciseness. The difference between FIGS. 1A and 1B is the connection between the Si interposer 120 and the logic chips 130. Instead of using the microbumps 132, the structure 110B uses hybrid bonding 134. As such, the difference is the junction between the Si interposer 120 and the logic chips 130. The structure 100B may be referred to as system-on-integrated-chip (SoIC) structure. The structure 100B may be referred to as a chip package or semiconductor package assembly or semiconductor chip device.

Hybrid bonding 134 may involve oxide bonding. That is, a layer of dielectric oxide may be deposited on the bonding surfaces of both the Si interposer 120 and the logic chips 130. When the two surfaces are brought together, the oxides bond through van der Waals forces. Post bond annealing enhances the bond by forming covalent bonds at the oxide interface. In one example, metal pads may be patterned on the surfaces of both the Si interposer 120 and the logic chips 130. The metal pads align and bond directly when the chips are pressed together, forming electrical connections. Direct metal-to-metal bonding eliminates the need for microbumps, thus reducing parasitic resistance and improving signal integrity. Further, the high-density interconnects enable wide input/output (I/O) interfaces, increasing data transfer rates between the Si interposer 120 and the logic chips 130.

FIG. 2 is a cross-sectional view of a memory configuration for the advanced packing technology including inductors and/or T-coils in the silicon interposer, according to an example.

FIG. 2 is similar to FIGS. 1A and 1B, and as such, a description of similar elements will be omitted for clarity and conciseness. In the structure 200, the Si interposer 120 includes inductors and/or T-coils 210. The structure 200 may be referred to as a chip package or semiconductor package assembly or semiconductor chip device.

The inductors and/or T-coils 210 may be placed within a KOZ 215. KOZs are areas around specific IP blocks, signal traces, or components where placing eDTCs is prohibited to avoid interference or performance degradation. These zones are defined based on EMI, thermal constraints, and routing congestion. eDTCs, especially those with high capacitance, can generate stray electric fields that may interfere with sensitive analog or high-speed digital IPs. Heat generated by nearby active IPs may affect the performance or reliability of eDTCs. Signal and power routing often involve dedicated spaces, preventing eDTC placement in heavily congested areas. To adhere to these KOZ requirements, the placement of eDTCs is restricted to non-critical areas of the Si interposer 120. This limitation necessitates optimizing their distribution across the available space to achieve the desired capacitance density without encroaching on sensitive zones.

The inductors and/or T-coils 210 may be placed within keep-out zones (KOZs) 215 to optimize the performance and minimize interference in high-frequency systems. The KOZs 215 are formed in the upper metal layers of the Si interposer 120, that is, in the metal routing layer 129. The KOZs 215 ensure adequate spacing between inductors and/or T-coils 210, and nearby signal traces or the TSVs 126. The inductors and/or T-coils 210 may generate magnetic fields, which can induce unwanted currents or noise in nearby traces, thus degrading signal integrity. Placing the inductors and/or T-coils 210 in the KOZs 215 reduces coupling effects and prevents signal degradation in high-speed interconnects. The inductors and/or T-coils 210 may further generate eddy currents, causing energy losses and reducing efficiency of the inductors and/or T-coils 210. The KOZs 215 minimize this interaction to ensure that the inductors and/or T-coils 210 are kept away from regions of the substrate with high conductive paths or the TSVs 126. The inductors and/or T-coils 210 may dissipate heat due to resistive losses. If they are placed too close to sensitive areas live the TSVs 126, thermal effects can affect device reliability. The KOZs 215 can thus provide a thermal buffer zone to prevent localized hotspots from impacting other components. Further, the inductors and/or T-coils 210 are used for bandwidth enhancement in high-speed signaling. Their high frequency operation can generate noise that interferes with neighboring circuitry. The KOZs 215 can act as a physical barrier, isolating these components and preventing noise from propagating into critical signal paths. As such, by positioning the inductors and/or T-coils 210 in the KOZs 215, the examples use the isolation offered by this reserved area in the Si interposer 120, leading to better performance, reliability, and signal integrity.

The inductor and/or T-coil 210 are formed by using upper metal layers in Si the interposer 120, which can help extend signal bandwidth by compensating channel losses. The integration of the inductors and/or T-coils 210 in the upper metal layers of the Si interposer 120 can provide impedance matching, signal filtering, and bandwidth extension, compensating for losses that occur in signal channels due to factors like parasitic capacitance, inductance, and resistance in the interposer and interconnects. By strategically placing these components in the upper metal layer of the Si interposer 120, designers can form inductive networks that work in tandem with the PDN and eDTCs to provide a more robust power and signal integrity solution. The inductor and/or T-coil 210 compensate for the inherent channel losses by adding inductive reactance to balance the impedance mismatches across the system, especially at higher frequencies. For T-coils, an additional complexity arises because they use a center tap for proper operation.

As such, in the case of using a T-coil, such approach involves employing one or more pads for a center tap (CT) 227. The CT 227 is an electrical connection made at the midpoint of a coil (or a pair of coupled coils). In other words, the CT 227 is a terminal or node that connects to the middle of the winding or coupled windings in a T-coil. In a T-coil topology, which includes inductive elements arranged in a “T” topology, the CT 227 connects to a reference voltage or power supply. This connection splits the T-coil into two equal parts, enabling symmetrical operation in differential circuits. When the T-coil is integrated into the Si interposer 120, it may need one or more pads (not shown) for the center tap connection. The one or more pads may provide a physical interface for connecting the CT 227 to the desired voltage, ground, or bias circuitry. The one or more pads may also ensure a low-resistance and low-inductance connection to minimize signal degradation.

Each logic chip 130 may include a transmitter 220, a receiver 222, and data in/out (DQ) blocks. Each logic chip 130 is connected to the Si interposer 120 via a power line 230 and a ground line 232. Each logic chip 130 is independently designed from the Si interposer 120. By designing the logic chips/dies separately from the Si interposer 120, a design engineer can independently optimize each component for its specific needs. For example, the die can be designed for high performance, low power consumption, or specific functionality, while the Si interposer 120 can be optimized for signal integrity, thermal management, and interconnect density. Also, the logic chips 130 and the Si interposer 120 can thus be manufactured separately, allowing for different yield strategies. Further, by designing a smaller interposer that is optimized for connectivity and power delivery, the overall size of the logic chips 10 or dies can be reduced.

The inductor and/or T-coil 210 send signals to the logic chips 130. The inductor and/or T-coil 210 may serve to provide impedance matching and/or signal conditioning to the logic chips 130 or die. The inductor and/or T-coil 210 may be used for high-frequency signal transmission, where the inductance helps in filtering or conditioning high-speed signals. The transmitter 220 may modulate and send out signals, whereas the receiver 222 may receive incoming signals. The receiver 222 processes these signals and demodulates them for use by the rest of the system.

The transmitter 220 on a logic chip 130 sends high-speed data signals to other components in the system, such as receivers on other logic chips or memory devices. The transmitter 220 is designed for high data rates, using differential signaling to minimize noise and interference. Features like pre-emphasis and equalization may be included to compensate for signal degradation caused by interconnect losses in the Si interposer 120. The transmitter (TX) drivers send signals through the microbumps 132 or the TSVs 126 in the Si interposer 120, which act as high-speed interconnects to other components like memory or adjacent logic chips.

The receiver 222 on the logic chip 130 processes incoming high-speed data from other chips or devices. The receiver 222 includes circuits to correct distortions or attenuations introduced during signal transmission. The receiver 222 extracts the clock signal from the received data stream and ensures proper timing alignment and receives low-noise differential signals over high-speed interconnects. The receiver 222 is connected to the Si interposer 120 to process signals routed from external sources like memory stacks, other chips, or off-chip I/O.

The DQ pins 225 are the primary data interface for transferring information between the logic chip 130 and other components, such as high-bandwidth memory (HBM) stacks or other logic devices. The DQ pins 225 may operate as part of a wide parallel data bus to enable high-bandwidth communication. Data may be transmitted as single-ended signals (e.g., double data rate (DDR)) or as differential pairs for better signal integrity. The DQ pins 225 are used in memory systems, where the DQ pins 225 work alongside data strobe signals for synchronized data transfer. The DQ pins 225 communicate directly with the TSVs 126 or the RDL 122 in the Si interposer 120 to connect to memory dies or adjacent chips.

Power (VDD) and ground (VSS) connections (e.g., the power line 230 and the ground line 232) provide the necessary operating voltages and return paths for the logic chip’s internal circuits. The Si interposer 120 includes dedicated power and ground planes with low impedance to support high-current demands. PDNs include decoupling capacitors and filtering techniques to minimize noise and ripple. Power delivery is scaled to support the increasing power demands of high-performance chips with multiple cores and integrated features. Power and ground signals are routed through microbumps, TSVs, or dedicated vias to planes within the Si interposer 120, which distributes these signals efficiently across the chip.

The Si interposer 120 uses the TSVs 126 and the RDL 122 to create high-density, low-latency connections between logic chips, memory stacks, and external components. Signals from the transmitters 220, the receivers 222, and the DQ pins 225 pass through these interconnects to other parts of the system. Power and ground planes in the Si interposer 120 help isolate high-speed signals from noise and crosstalk.

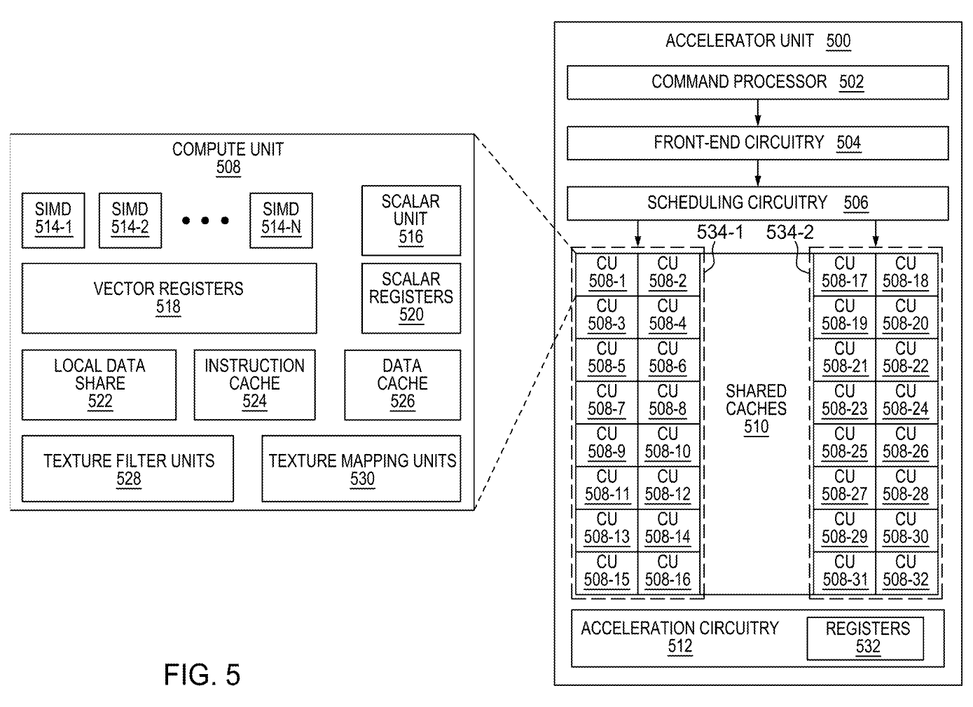

The DQ pins 225 are the primary data interface pins on the logic chips 130, used to transfer data between the logic chips 130 and other components connected via the Si interposer 120. The DQ pins 225 facilitate high-speed communication and efficient data transfer in systems that rely on interposers for advanced packaging. The DQ pins 225 are used to transmit and receive data between logic chips 130 (e.g., central processing units (CPUs), graphics processing units (GPUs), or artificial intelligence (AI) accelerators, as described in detail with reference to FIG. 5) and high-bandwidth memory (HBM) stacks connected through the Si interposer 120. The data signals from the DQ pins 225 are routed using the TSVs 126 or the RDL 122 in the Si interposer 120 to reach the destination (e.g., memory or other logic chips).

Therefore, according to FIG. 2, the use of the inductors and/or T-coils 210 in the KOZs 215 of the Si interposer 120 enables high-speed signal operation, particularly for data rates exceeding 10 Gbps per pin. These components are strategically integrated into the Si interposer 120 to extend the signal bandwidth and enhance signal integrity, which are beneficial for high-performance computing and memory systems.

High-speed signal transmission over Si interposers is challenging due to parasitic capacitance and signal attenuation caused by the dense routing and micro-bumps used in interposer designs. Parasitic capacitance arises from the close proximity of interconnects and the dielectric properties of the interposer material, which limits the signal bandwidth. Inductors, with their ability to store energy in a magnetic field, act as a counterbalance to capacitance, reducing the low-pass filtering effect that degrades high-frequency signals. By doing so, inductors help maintain the integrity of high-speed signals and ensure minimal distortion as they travel through the interposer.

In a T-coil structure, inductors are arranged in a way that effectively reduces the capacitive loading seen by the signal path. This is achieved by splitting the capacitance across multiple branches of the T-coil network, allowing high-frequency signals to propagate with reduced attenuation. The result is a significant improvement in bandwidth, which is valuable in applications such as HBM and 2.5D integrated circuits where data rates of 10 Gbps or higher are needed.

Placing the inductors and/or T-coils 210 in the KOZ 215 ensures they are not adversely affected by other elements of the Si interposer 120. The KOZ 215, a designated area free of active circuitry, reduces EMI and coupling effects that may otherwise compromise the performance of these components. The physical isolation provided by the KOZ 215 also minimizes parasitic interactions with nearby interconnects, allowing the inductors and/or T-coils 210 to operate more efficiently. Additionally, this placement helps maintain thermal stability, as inductive components can be sensitive to temperature variations that may occur near active circuitry.

Further, integrating these inductive components in the upper metal layer of the Si interposer 120 offers several advantages. It allows for compact integration of inductive elements without the use of additional board space. By positioning the inductors and/or T-coils 210 closer to the signal routing paths, designers can achieve low-latency signal transmission with less loss and reflection, especially in high-speed memory and communication interfaces like DRAM, GPU, AI accelerator, and CPU designs. Additionally, these components can help filter high-frequency noise and improve the power integrity by stabilizing voltage fluctuations and suppressing high-frequency noise from the PDN.

Another advantage of using the inductors and/or T-coils 210 in high-speed systems is their ability to improve power efficiency. By minimizing signal distortion and reducing the need for additional amplification or equalization circuits, these components help lower overall power consumption. This efficiency is beneficial in systems where high-speed operation is balanced with energy constraints, such as AI accelerators and data centers. Thus, the integration of inductors and/or T-coils into the Si interposer’s KOZ serves a dual purpose, that is, extending signal bandwidth and enabling reliable high-speed operation beyond 10 Gb/s per pin.

FIG. 3A illustrates a first memory configuration where two data in/out (DQ) blocks share one embedded deep trench capacitor (eDTC), according to an example.

In conventional configurations, each eDTC can be assigned to a single DQ. While the use of an eDTC for each individual DQ pin can provide high levels of localized power decoupling and noise suppression, there are disadvantages associated with this approach.

One disadvantage of using one eDTC per DQ block is the excessive use of layout space. Each eDTC occupies a specific area on the Si interposer, and when one eDTC is dedicated to every DQ block, it can consume a significant portion of the available area. This can limit the available space for other components such as memory cells, logic units, or additional pins. In high-density designs, especially in DRAM and processors (e.g., CPUs or GPUs or AI accelerators, as described in detail with reference to FIG. 5), this layout inefficiency becomes an issue as the demand for more data pins grows. Another disadvantage of having an eDTC dedicated to each DQ block is increased design complexity. Each capacitor needs to be integrated and routed independently, increasing the overall number of connections and making it harder to maintain a clean, efficient signal path. Complex routing is needed to ensure that each eDTC is placed correctly, leading to longer development times and more complicated verification processes. The increased routing complexity can lead to signal integrity issues, such as crosstalk, if not properly managed, as the routing paths of the capacitors and signal lines become intertwined. One further disadvantage of having an eDTC dedicated to each DQ block is the increase in component count. More components on the chip translate to higher fabrication costs due to the need for more complex photomasks and additional process steps and increased material costs, as more area is taken up by each individual eDTC. Manufacturing these capacitors involves sophisticated processes that increase cost, especially when they are densely integrated. Also, with a larger number of components, there is an increase in the risk of yield losses. A failure in any of the capacitors may lead to a faulty memory subsystem, resulting in more stringent testing and quality assurance procedures. The increase in defective parts can affect the overall profitability of the manufacturing process. Finally, one further disadvantage of having an eDTC dedicated to each DQ block is the number of individual eDTCs needed for each DQ block may lead to an increase in power consumption. Each eDTC consumes some amount of power for its operation, and with one eDTC per pin, the system’s overall power budget may be impacted.

The memory configurations of FIGS. 3A and 3B resolve such issues by assigning multiple DQ blocks to one single or common eDTC. A distinction is also made between the terms DQ pin and DQ block. A DQ pin may also be referred to as a DQ pad. The DQ pin is a point that merges TX and RX signals. The DQ pin has a long route to the bumps 114 to send and receive signals from/to the outside. As such, the DQ pin and the eDTC are shared in an area of the Si interposer 120. In contrast, a DQ block includes TX, RX, and DQ pins. The eDTC shares its physical connection with the DQ blocks power and ground. The eDTC thus helps to suppress the noise of the TX and RX circuitry. The eDTC is not physically connected to the DQ pin. Thus, the DQ pin is a single data path used in the data I/O, whereas the DQ block is a broader functional unit that includes TX (driving of the data onto the DQ pins), RX (capturing incoming data from the DQ pins), and DQ pins that are the actual data interface for transferring bits. The DQ block provides a structural way to handle data movement, whereas the DQ pins serve as the actual electrical conduits for the data transmission.

In the first memory configuration 300A, there may be four different inductors and/or coils in the Si interposer 120 connected to four different DQ blocks (in the same logic chip). In one non-limiting example, a first inductor and/or coil 210A is connected to first DQ pins 225A of a first logic chip, a second inductor and/or coil 210B is connected to second DQ pins 225B of a second logic chip, a third inductor and/or coil 210C is connected to third DQ pins 225C of a third logic chip, and a fourth inductor and/or coil 210D is connected to fourth DQ pins 225D of a fourth logic chip. The first DQ pins 225A and the second DQ pins 225B may be associated with a common eDTC, that is, a first eDTC 302. Similarly, the third DQ pins 225C and the fourth DQ pins 225D may be associated with a common eDTC, that is, a second eDTC 304. Thus, each eDTC may be coupled to two DQ blocks.

FIG. 3B illustrates a second memory configuration where four DQ blocks share one eDTC, according to an example.

In the second memory configuration 300B, there may be four different inductors and/or coils in the Si interposer 120 connected to four different DQ blocks. In one non-limiting example, a first inductor and/or coil 210A is connected to first DQ pins 225A of a first logic chip, a second inductor and/or coil 210B is connected to second DQ pins 225B of a second logic chip, a third inductor and/or coil 210C is connected to third DQ pins 225C of a third logic chip, and a fourth inductor and/or coil 210D is connected to fourth DQ pins 225D of a fourth logic chip. The first DQ block, the second DQ block, the third DQ block, and the fourth DQ block may be associated with a common eDTC, that is, a common eDTC 306. Thus, each eDTC may be associated with four DQ blocks of four logic chips. Each eDTC may be associated with any number of DQ block, for example, 6 DQ block, 8 DQ block, 10 DQ block or more. The number of DQ block associated with a single, common eDTC may vary based on design choices.

Moreover, in both FIGS. 3A and 3B, the eDTCs are not connected or coupled to the inductor and/or T-coil. The eDTCs are merely associated with various inductors and/or T-coils. The eDTCs are not physically connected or coupled to the inductors and/or T-coils 210. Instead, the eDTCs are directly connected to the power line 230 and the ground line 232 of the dies or logic chips 130. Direct connections to the power line 230 and the ground line 232 of the dies allow the eDTCs to provide more stable and reliable power delivery. This helps maintain consistent voltage levels, reducing the likelihood of voltage fluctuations. A direct connection to the ground of each die helps establish a solid reference for the signal paths, which improves the overall signal integrity. The eDTCs, being directly connected to the power and ground of the dies, can help in reducing EMI and noise. As such, from the logic chip/die perspective, there is power and there are signals, which are separate and distinct. The power is connected to the eDTCs and the signals are communicated to the inductors and/or T-coils 210.

As such, FIGS. 3A and 3B present the sharing of one eDTC with multiple DQ blocks. This approach balances resource utilization, signal integrity, and power efficiency in 2.5D systems with Si interposers. The single, common eDTC serves as a centralized point responsible for managing signal timing and synchronization across multiple DQ blocks. In high-speed communication systems, each DQ pin transmits or receives data at high rates, often exceeding 10 Gb/p per pin. A single, common eDTC provides the clocking and timing references for multiple DQs to ensure synchronized data transfer. Sharing a single eDTC among several DQs reduces the complexity and area overhead associated with duplicating timing circuits for each DQ pin. As such, a shared eDTC eliminates the need for a dedicated timing circuit for each DQ pin, reducing the silicon area used. A shared or centralized eDTC also simplifies the distribution of clock signals across multiple DQ pins. The combined use of a shared eDTC and inductors and/or T-coils ensures high-speed data can flow reliably across multiple DQ pins without sacrificing performance.

In a practical application, when frequency and time domain simulations are performed, when one eDTC per DQ block is used, an 82% peak magnitude reduction in the frequency domain and a 46.4% voltage drop at the Si interposer top side (e.g., HB side) in the time domain is exhibited. In addition, if 2 or 4 DQ blocks share one eDTC, even though there is a 5% or 12% penalty in the frequency domain and a 0.9% and 5.9% penalty in the time domain, respectively, the system can exhibit a 50% or 75% layout area advantage. If 8 DQ blocks share one eDTC, it can save even more layout area, however, the penalty may sharply increase to 18.9% compared to one eDTC per DQ block.

Therefore, sharing a single eDTC with multiple inductors reduces the number of components needed, simplifying the overall design and lowering the cost. Fewer eDTCs reduces the number of interconnections, minimizing potential signal routing complexity. However, since a single eDTC is responsible for multiple inductors, this configuration may have limited scalability. If the inductors need different power levels or signal conditioning, sharing one eDTC may strain the system. With two eDTCs, the load is split between them, potentially improving the efficiency and reducing the chance of overloading any single eDTC. With two eDTCs, there is a higher likelihood that each inductor is better matched with the eDTC’s capabilities. This allows for improved signal routing. However, adding another eDTC increases the overall complexity of the system. More interconnections are needed, which leads to an increased cost. As such, as the number of eDTCs increases, the system becomes more complex and more interconnections are needed, which could lead to increased design challenges. However, the system can handle more inductors with more efficient power and signal management. Increasing the number of eDTCs improves system performance by ensuring better load distribution, signal integrity, and scalability. However, each additional eDTC adds cost and space requirements. The more eDTCs are used, the greater the ability to scale the system and adapt it to different inductors and operational conditions. Choosing between these configurations depends on the system’s specific needs, such as required scalability, performance, cost constraints, and the number of inductors involved. The tradeoff is between simplicity and cost, and flexibility, performance, and scalability.

As such, the number of eDTCs is selectable. Stated differently, depending on the number of inductors in use or the complexity of the system, the number of eDTCs can be adjusted to balance performance and resource utilization. For example, in low-power or low-complexity applications, fewer eDTCs can be used to reduce power consumption and cost, while in high-performance systems, more eDTCs can be activated to ensure robust power delivery and signal integrity. As the system requirements change (e.g., more inductors are added), the number of eDTCs can be increased to meet the new demands. If the system can adjust the number of eDTCs based on workload, it can optimize power usage. For example, during periods of low activity or when fewer inductors are needed, the system can deactivate some eDTCs to conserve energy. Further, with the ability to select the number of eDTCs, signal integrity can be optimized by choosing to activate only the number of eDTCs that are necessary for a given operation. This helps minimize crosstalk and interference by ensuring that only the required number of paths are active.

The optimal placement of eDTCs between DQ block in high-speed memory systems offers a number of significant benefits, particularly when these eDTCs are shared across multiple DQ blocks. These advantages extend to areas like power integrity, signal integrity, space optimization, and overall system performance.

eDTCs placed between DQ pins provide localized decoupling, which helps stabilize the power supply to the DQ pins. Since the DQ pins are the primary points for high-speed data transfer, they are often vulnerable to power noise, such as SSN and SSO, which can degrade signal integrity. By positioning eDTCs near these pins, the capacitors can filter high-frequency noise that arises from switching events at DQ pins and they maintain consistent voltage levels across the system, thereby reducing voltage fluctuations that may lead to jitter or signal distortion. By sharing a single eDTC across multiple DQ pins, the system benefits from global power noise suppression across the data channels. This method helps mitigate the collective impact of SSN and SSO across multiple pins simultaneously. The shared eDTC acts as a bulk charge reservoir, ensuring stable power delivery and minimizing fluctuations from high-speed switching across multiple DQ lines. SSN, also known as ground bounce or VDD droop, refers to transient voltage fluctuations in the power and ground planes caused by multiple output drivers switching states (e.g., from LOW to HIGH or HIGH to LOW) at the same time. SSO refers to the scenario where multiple output drivers (e.g., input/output (I/O) pins) on a chip switch simultaneously, creating transient electrical and thermal stresses on the chip and the power delivery network.

Crosstalk is a further challenge in high-speed systems where signals from adjacent data lines interfere with one another, especially when multiple DQ pins are packed close together. The integration of eDTCs between DQ pins helps reduce the likelihood of electromagnetic coupling between adjacent DQs by acting as a shielding mechanism and reduce signal degradation due to power noise to ensure that the data signals are clean and stable during transmission. By placing eDTCs between DQ pins, these capacitors not only provide decoupling but also isolate the power planes from the signal paths, enhancing the integrity of the transmitted signals. Maintaining a stable voltage is valuable for high-speed data transmission. With eDTCs between DQ pins, the capacitors help smooth out any power rail fluctuations, thereby reducing jitter and minimizing the chance of timing errors that can result from rapid switching of the DQ pins. This translates to more accurate data transfer and improved clock synchronization.

High-speed memory systems, such as DRAM, involve densely packed layouts. By sharing eDTCs between multiple DQ pins, the number of individual capacitors needed in the layout is significantly reduced, allowing for more efficient use of available space. This space-saving strategy helps integrate more memory cells or other functional components within the same chip footprint. The shared eDTCs enable a compact design that doesn't compromise on performance, allowing for a better balance between capacitance and area usage. By distributing the decoupling responsibility across fewer, shared eDTCs, the system reduces the overall number of capacitors used. This reduces the complexity of the interposer design and simplifies manufacturing and routing by minimizing the need for individual decoupling capacitors for each DQ pin.

Sharing eDTCs across multiple DQ pins further ensures that the PDN is more efficient. This helps to balance the charge load across the DQ pins, ensuring that high-speed data transfers do not cause excessive voltage drops or power rail fluctuations and helps minimize the power losses seen when multiple individual decoupling capacitors are used. eDTCs not only provide noise filtering but also help manage thermal behavior. When capacitors are located between DQ pins, they help absorb transient power spikes, reducing the thermal stress on both the Si interposer and the memory components.

Therefore, placing eDTCs between DQ pins in high-speed memory systems delivers multiple benefits, including enhanced power integrity, improved signal quality, optimized layout, and better overall system performance. Sharing these eDTCs across multiple DQ pins further optimizes the system by reducing layout area, minimizing component count, and providing efficient power and thermal management. This approach ensures that high-speed memory systems can operate reliably and efficiently, even as data rates and system complexity continue to increase.

FIGS. 3C-3F are inductor coil designs, according to an example.

In FIG. 3C, circuit 300C1 shows a top die IP 310 coupled to an interposer 320. The top die IP 310 includes a transmitter 220, a receiver 222, and an electrostatic discharge (ESD) component 312. The interposer 320 includes a first inductor 322, a second inductor 324, and an end 326 (V_{end}) of the inductor coil. The end 326 is connected to the BGA 105. In circuit 300C1, the inductor coil is connected with connection 330A. The transmitter 220 is connected to the receiver 222. The ESD component 312 has a separate connection.

In FIG. 3C circuit 300C2 shows the IP 310 (which may not be the top die) coupled to the interposer 320. The IP 310 includes the transmitter 220, the receiver 222, and the ESD component 312. The interposer 320 includes the first inductor 322, the second inductor 324, and the end 326 (V_{end}) of the inductor coil. The end 326 is connected to the BGA 105. In circuit 300C2, the inductor coil configuration is connected with connection 330B. The transmitter 220 is connected to the first inductor 322 alone. The receiver 222 and the ESD component 312 are connected between the first inductor 322 and the second inductor 324. The inductor coil connections for the RX and TX can be swappable.

In FIG. 3D, circuit 300D1 shows a top die IP 310 coupled to an interposer 320. The top die IP 310 includes the transmitter 220, the receiver 222, and the ESD component 312. The interposer 320 includes the first inductor 322, the second inductor 324, the end 326 (V_{end}) of the inductor coil, as well as a capacitor 335. The end 326 is connected to the BGA 105. In circuit 300D1, the transmitter 220 is connected to the receiver 222. The ESD component 312 has a separate connection.

In one example, the capacitor 335 may be placed in parallel to the first inductor 322 and the second inductor 324. The performance impact can be that the capacitor 335 can store and return energy efficiently, improving selectivity in frequency-sensitive applications. The placement of the capacitor 335 may depend on frequency response, impedance, and energy transfer requirements.

In FIG. 3D circuit 300D2 shows the IP 310 (which may not be the top die) coupled to the interposer 320. The IP 310 includes the transmitter 220, the receiver 222, and the ESD component 312. The interposer 320 includes the first inductor 322, the second inductor 324, the end 326 (V_{end}) of the inductor coil, as well as the capacitor 335. The end 326 is connected to the BGA 105. In circuit 300D2, the transmitter 220 is connected to the first inductor 322 alone. The receiver 222 and the ESD component 312 are connected between the first inductor 322 and the second inductor 324. The inductor coil connections for the RX and TX can be swappable. The placement of the capacitor 335 may depend on frequency response, impedance, and energy transfer requirements when the inductor configurations is connected to the receiver 222.

With multiple inductors in the interposer, the performance impact may relate to higher flexibility in optimizing transfer efficiency, increased parasitics, and more design complexity due to added resonance conditions. The tradeoff may be between efficiency, complexity, sensitivity to alignment, and based on application suitability.

In FIG. 3E, circuit 300E1 shows a top die IP 310 coupled to an interposer 320. The top die IP 310 includes the transmitter 220, the receiver 222, and the ESD component 312. The transmitter 220 is connected to an inductor 340. The interposer 320 includes the first inductor 322, the second inductor 324, and the end 326 (V_{end}) of the inductor coil. The end 326 is connected to the BGA 105. In circuit 300E1, the inductor coil configuration includes an inductor not just in the interposer 320, but also in the top die IP 310, where the inductor 340 is connected to the transmitter 220.

In FIG. 3E, circuit 300E2 shows the IP 310 (which may not be the top die) coupled to an interposer 320. The IP 310 includes the transmitter 220, the receiver 222, and the ESD component 312. The transmitter 220 is connected to an inductor 340. The interposer 320 includes a single inductor 342 and the end 326 (V_{end}) of the inductor coil. The end 326 is connected to the BGA 105. In circuit 300E2, the inductor coil configuration includes the single inductor 342 in the interposer 320 and the inductor 340 connected to the transmitter 220 in the IP 310. Thus, the number of inductors within the interposer and the IP 310 can be changed depending on performance requirements. With one inductor in the IP and one inductor in the interposer, the performance impact may relate to efficiency at close distances, limited tunability for impedance matching, and a fixed coupling coefficient. It may also result in stronger magnetic coupling for better efficiency. The tradeoff may be between efficiency, complexity, sensitivity to alignment, and based on application suitability. For example, more inductors can help mitigate misalignment, but may need careful tuning. Higher frequencies improve coupling, but may increase losses.

In FIG. 3F, circuit 300F shows a first top IP 310A and a second top IP 310B connected to the interposer 320. The first top IP 310A includes a TX and RX, whereas the second top IP 310B includes a TX, RX, and ESD. The first top IP 310A is coupled to the inductors of the interposer 320, whereas the end 326 (V_{end}) is connected, via connection 345, to the second top IP 310B. The number of inductors on the interposer 320 can be selected based on coupling efficiency and layout constraints. Metrics for inductive coupling may include coupling efficiency, quality factor, and power transfer efficiency. The tradeoffs may include higher frequency, more turns in the inductor, and misalignment impact. Metrics for direct interposer connection to the second top IP 310B may include signal integrity, power loss, resistance, and capacitance. The tradeoffs may include shorter interposer traces and an impact of high-speed signal integrity.

FIG. 3G illustrates different inductor configurations used in the dies and in the interposer, according to an example.

The chiplet 350 may include a first IP 352, a second IP 354, and a third IP 356. The first IP 352 may be a die of a 7nm process node, the second IP 354 may be a die of a 3nm process node, and the third IP 356 may be a die of a 10nm process node. Each die may include multiple TX, RX, and ESDs. Some of the die may include inductors, whereas other die does not include inductors. In one example, the second IP 354 may include a single inductor 370 connected to a RX and a pair of inductors 372 connected to a different TX. The first IP 352 and the third IP 356 may not include any inductors. The first IP 352, the second IP 354, and the third IP 356 are coupled to the interposer 120 via connections 132, 134. The interposer 120 may include several inductor configurations coupled to the first IP 352, the second IP 354, and the third IP 356. For example, inductor configuration 360 may be connected to a RX and inductor configuration 362 may be connected to a TX in the first IP 352. Inductor configuration 374 may be connected to a TX/RX and inductor configuration 376 may be connected to a TX of the second IP 354. Inductor configuration 380 may be connected to the TX of the third IP 356. For smaller nodes, there is higher transistor density but lower Q-factor due to increased metal resistance. Inductors on the interposer may be preferable to reduce losses. As such, the second IP 354 includes more inductors than the 10nm process node.

The benefits of having more inductors in the interposer include higher Q-factor (lower losses), easier heat dissipation, better inductive coupling for power transfer, and dedicated inductive links for data transfer. The benefits of having inductors in the IP or die include shorter signal paths for localized inductive coupling, customization for process node advantages, and dynamic reconfiguration. The benefits of having inductors in both the interposer and the IP or die include having stacked inductors for higher efficiency, adaptive load sharing, and enabling multi-mode operation. A system may use the interpose inductors for high-power mode and on-chip inductors for low-power mode to optimize efficiency. If efficiency is a high priority, interposer-based inductors may be best for power transfer. If integration with active circuits is necessary, IP-based inductors may be better for radiofrequency (RF) and short-range signal transfer.

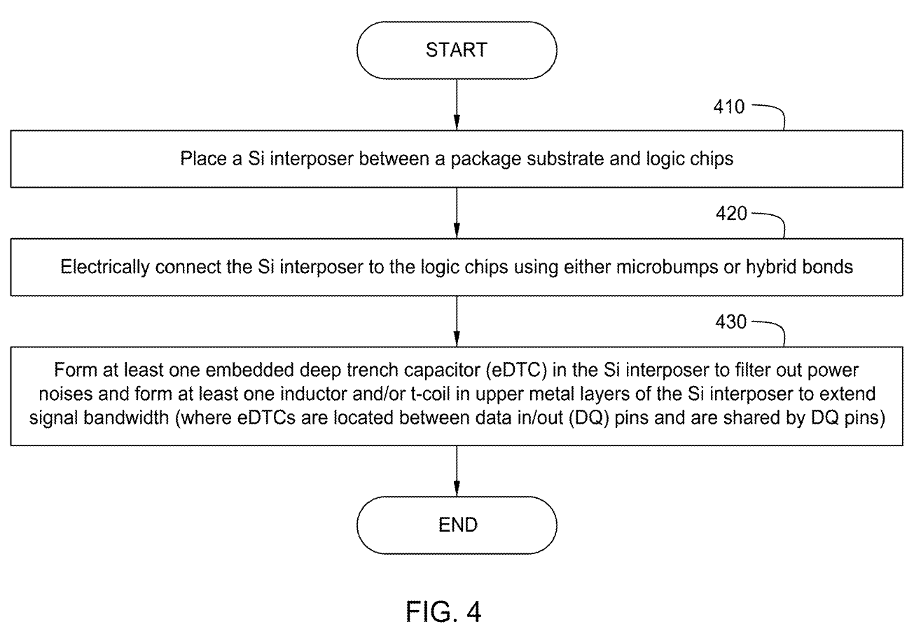

FIG. 4 illustrates a method for providing an optimized memory configuration in a Si interposer, according to an example.

At 410, a Si interposer is placed between a package substrate and logic chips. The Si interposer formed over the package substrate may include a RDL, an interposer layer, and a metal routing layer.

At 420, the Si interposer is electrically connected to the logic chips using either microbumps or hybrid bonds. A CoWoS structure uses microbumps and a SoIC structure uses hybrid bonds which is much smaller than microbumps.

At 430, at least one eDTC is formed in the Si interposer to filter out power noises. Additionally, at least one inductor and/or T-coil is formed in upper metal layers of the Si interposer to extend signal bandwidth. The eDTCs are located between DQ pins and are shared by DQ blocks.

Forming eDTCs in Si interposers offers significant advantages in enhancing system performance, particularly by improving signal integrity. Signal integrity refers to the accurate and reliable transmission of signals without distortion or interference, which is valuable in high-speed DRAM, logic chips, and other advanced systems. Optimal placement of eDTCs ensures signal integrity, offering benefits including reduced power noise, crosstalk mitigation, improved signal timing, reduced jitter, enhanced high-frequency signal performance, and better power-signal isolation.

PDNs in high-speed systems are prone to noise due to rapid changes in current demands from switching logic. This noise can couple into signal traces and cause jitter, delay, or degradation in signal quality. Optimal eDTC placement reduces power noise by providing localized decoupling close to the source of noise, such as high-speed logic blocks or memory. By minimizing voltage fluctuations, eDTCs prevent power noise from interfering with signal lines, ensuring stable and clean signal transmission.

Crosstalk occurs when signals in adjacent traces interfere with each other due to electromagnetic coupling. This issue is heightened in dense interposer layouts with tightly packed signal traces. Placing eDTCs strategically between high-speed signal paths and power/ground planes provides additional shielding and reduces electromagnetic coupling. This placement ensures lower cross-channel interference, improving the overall signal fidelity in the system.

Signal timing and jitter are consequential in high-speed operations, where even small variations can lead to data errors. Localized decoupling with eDTCs ensures stable voltage levels across the PDN, minimizing timing delays caused by power fluctuations. Reduced noise coupling into clock and data lines leads to tighter control of timing margins and lower jitter, enabling higher data rates without compromising reliability.

High-speed systems often operate in the gigahertz (GHz) frequency range, where parasitic inductance and impedance mismatches in the PDN can degrade signal performance. Low-inductance eDTCs embedded in proximity to high-speed circuits offer effective decoupling at high frequencies, maintaining a stable power supply. This stability ensures signal integrity when encountering rapid switching events, allowing for higher data throughput and reduced error rates.

In Si interposers, the coexistence of dense signal routing, power delivery, and decoupling elements increases the risk of power-signal coupling, leading to signal degradation. Strategically placed eDTCs improve the power-signal isolation by acting as local reservoirs of charge, reducing the need for signals to traverse noisy power paths. This separation enhances the overall signal-to-noise ratio (SNR) and reduces the likelihood of signal interference from power delivery noise.

By reducing power noise, minimizing crosstalk, improving timing accuracy, and enhancing high-frequency performance, eDTCs enable robust and reliable signal transmission. These benefits help achieve the high data rates, low error rates, and scalability needed in next-generation electronic systems, particularly in high-speed DRAM and processor architectures. However, eDTCs alone may not be sufficient in achieving such benefits. As such, the examples also incorporate inductors and/or T-coils in the Si interposer with the eDTCs to further enhance high-speed operation, e.g., of more than 10 Gbps per pin.

Such approach involves the combined use of inductors and/or T-coils to extend bandwidth, paired with eDTCs in Si interposers to filter out power noise, such as SSN and SSO. These elements, when strategically placed, can significantly enhance signal and power integrity while optimizing layout efficiency.

High-speed signals need transmission lines with wide bandwidth to maintain signal fidelity. Inductors and T-coils, as passive components, are effective tools for bandwidth extension. Inductors serve as impedance-matching elements that help counteract parasitic capacitance, thereby reducing signal distortion at high frequencies. T-coils function as series-connected or transformer-like configurations, splitting the signal path into two balanced branches. This effectively doubles the bandwidth by halving the load capacitance seen by the driver. By integrating these components within the Si interposer, systems can achieve higher data rates while maintaining robust signal integrity, even under stringent high-speed conditions.

When combined, inductors, T-coils, and eDTCs create a complementary system that addresses both signal and power integrity challenges. Inductors and T-coils extend the signal bandwidth, ensuring high-speed operation with minimal distortion. eDTCs filter out power noise, reducing jitter and improving signal stability. Together, they form a robust infrastructure for achieving error-free communication in high-speed designs.

Strategic placement of these components is valuable in maximizing their effectiveness while optimizing the layout area. For example, inductors can be placed near high-speed drivers to match impedance and reduce signal distortion. T-coils can be integrated along signal paths, especially in densely routed areas, to split and balance the signal load. eDTCs can be placed close to power-intensive regions, such as DRAM cores and logic blocks, for localized decoupling. Integrating inductors, T-coils, and eDTCs into a single Si interposer involves thoughtful layout planning to avoid congestion and maintain performance. In the examples, eDTCs can be used to achieve maximum capacitance in minimal space, freeing up room for other components. Vertical stacking or multiple interposer layers can be used to separate inductors, T-coils, and eDTCs from signal and power routing. Further, keep-out zones (KOZs) may be employed to ensure placement respects keep-out zones for sensitive IP blocks and signal traces to prevent interference.

FIG. 5 is a block diagram of an accelerator unit (AU) configured to execute workloads for applications running on a processing system, in accordance with some examples.

FIG. 5 presents an AU 500 configured to execute workloads for one or more applications running on a processing system. These applications include, for example, compute applications, graphics applications, or both each configured to issue respective series of instructions, also referred to herein as “threads,” to a central processing unit (CPU) of the processing system. Compute applications, when executed by a processing system, cause the processing system to perform one or more computations, such as machine-learning, neural network, high-performance computing, or databasing computations. Further, graphics applications, when executed by a processing system, cause the processing system to render a scene including one or more graphics objects and, as an example, output the scene on a display. The instructions issued to the CPU from these applications, for example, include groups of threads, also referred to herein as “workgroups,” to be executed by AU 500. To perform these workgroups, AU 500 includes one or more vector processors, coprocessors, graphics processing units (GPUs), general-purpose GPUs, non-scalar processors, highly parallel processors, artificial intelligence (AI) processors, inference engines, AI engines, AI engine cores, machine-learning processors, or any combination thereof. As an example, AU 500 includes one or more command processors 502, front-end circuitry 504, scheduling circuitry 506, compute units 508, shared caches 510, and acceleration circuitry 512. The acceleration circuitry 512 may include first functional circuitry and second functional circuitry for concurrently performing matrix-matrix and vector-vector instructions and/or operations (parallel execution).

A command processor 502 of AU 500 is configured to receive, from the CPU, a command stream indicating one or more workgroups to be executed. As an example, based on a compute application running on the processing system, the command processor 502 receives a command stream indicating workgroups that involve compute operations such as matrix multiplication, addition, subtraction, and the like to be performed. As another example, based on a graphics application running on the processing system, the command processor 502 receives a command stream indicating workgroups that include draw calls for a scene to be rendered. After receiving a command stream, the command processor 502 parses the command stream and issues respective instructions of the indicated workgroups to front-end circuitry 504, scheduling circuitry 506, or both. As an example, based on a command stream from a graphics application, the command processor 502 issues one or more draw calls to front-end circuitry 504 that includes one or more vertex shaders, polygon list builders, and the like. From the instructions issued from the command processor 502, front-end circuitry 504 is configured to position geometry objects in a scene, assemble primitives in a scene, cull primitives, perform visibility passes for primitives in a scene, generate visible primitive lists for a scene, or any combination thereof. For example, based on a set of draw calls received from a command processor 502, front-end circuitry 504 determines a list of primitives to be rendered for a scene. After determining a list of primitives to be rendered for a scene, the front-end circuitry 504 issues one or more draw calls (e.g., a workgroup) associated with the primitives in the list of primitives to scheduling circuitry 506.

Based on the instructions of the workgroups received from a command processor 502, front-end circuitry 504, or both, scheduler circuitry 506 is configured to provide data indicating threads (e.g., operations for these threads) to be executed for these workgroups to one or more compute units 508. Each compute unit 508 is configured to support the concurrent execution of two or more threads of a workgroup. For example, each compute unit 508 is configured to concurrently execute a predetermined number of threads referred to herein as a “wavefront.” Based on the size of the wavefront of a compute unit 508, scheduler circuitry 506 schedules one or more groups of threads of the workgroup, also referred to herein as “waves,” to be executed by the compute unit 508. As an example, scheduler circuitry 506 first updates one or more registers of a compute unit 508 such that the compute unit 508 is configured to execute a first group of waves of the workgroup. After the compute unit 508 has executed the first group of waves, scheduler circuitry 506 updates one or more registers of the compute unit 508 to schedule a second group of waves of the workgroup to be executed by the compute unit 508. To execute these waves, each compute unit is connected to one or more shared caches 510 that each include a volatile memory, non-volatile memory, or both accessible by one or more compute units 508. These shared caches 510, for example, are configured to store data (e.g., register files, values, operands, instructions, variables) used in the execution of one or more waves, data resulting from the performance of one or more waves, or both. Because a shared cache 510 is accessible by two or more compute units 508, a first compute unit 508 is enabled to provide results from the execution of a first wave to a second compute unit 508 executing a second wave. Though the example presented in FIG. 5 shows AU 500 as including 32 compute units (508-1 to 508-32), in other implementations, AU 500 can include any number of compute units 508.

Each compute unit 508 includes one or more single instruction, multiple data (SIMD) units 514, a scalar unit 516, vector registers 518, scalar registers 520, local data share 522, instruction cache 524, data cache 526, texture filter units 528, texture mapping units 530, or any combination thereof. A SIMD unit 514 (e.g., a vector processor) is configured to concurrently perform multiple instances of the same operation for a wave. For example, a SIMD unit 514 includes two or more lanes each including an arithmetic logic unit (ALU) and each configured to perform the same operation for the threads of a wave. Though the example presented in FIG. 5 shows a compute unit 508 including three SIMD units (514-1, 514-2, 514-N) representing an N number of SIMD units, in other implementations, a compute unit 508 can include any number of SIMD units 514. Further, as an example, the size of a wavefront supported by AU 500 is based on the number of SIMD units 514 included in each compute unit 508. To determine the operations performed by the SIMD units 514, each compute unit 508 includes vector registers 518 formed from one or more physical registers of AU 500. These vector registers 518 are configured to store data (e.g., operands, values) used by the respective lanes of the SIMD units 514 to perform a corresponding operation for the wave. Additionally, each compute unit 508 includes a scalar unit 516 configured to perform scalar operations for the wave. As an example, the scalar unit 516 includes an ALU configured to perform scalar operations. To support the scalar unit 516, each compute unit 508 includes scalar registers 520 formed from one or more physical registers of the AU 500. These scalar registers 520 store data (e.g., operands, values) used by the scalar unit 516 to perform a corresponding scalar operation for the wave.

Further, each compute unit 508 includes a local data share 522 formed from a volatile memory (e.g., random-access memory) accessible by each SIMD unit 514 and the scalar unit 516 of the compute unit 508. That is to say, the local data share 522 is shared across each wave concurrently executing on the compute unit 508. The local data share 522 is configured to store data resulting from the execution of one or more operations for one or more waves, data (e.g., register files, values, operands, instructions, variables) used in the execution of one or operations for one or more waves, or both. As an example, the local data share 522 is used as a scratch memory to store results necessary for, aiding in, or helpful for the performance of one or more operations by one or more SIMD units 514. The instruction cache 524 of a compute unit 508, for example, includes a volatile memory, non-volatile memory, or both configured to store the instructions to be executed for one or more waves to be executed by the compute unit 508. Further, the data cache 526 of a compute unit 508 includes a volatile memory, non-volatile memory, or both configured to store data (e.g., register files, values, operands, variables) used in the execution of one or more waves by the compute unit 508. The instruction cache 524, data cache 526, shared caches 510, and a system memory, for example, are arranged in a hierarchy based on the respective sizes of the caches. As an example, based on such a cache hierarchy, a compute unit 508 first requests data from a controller of a corresponding data cache 526. Based on the data not being in the data cache 526, the data cache 526 requests the data from a shared cache 510 at the next level of the cache hierarchy. The caches then continue in this way until the data is found in a cache or requested from the system memory, at which point, the data is returned to the compute unit 508. Additionally, each compute unit 508 includes one or more texture mapping units 530 each including circuitry configured to map textures to one or more graphics objects (e.g., groups of primitives) generated by the compute units 508. Further, each compute unit 508 includes one or more texture filter units 528 each having circuitry configured to filter the textures applied to the generated graphics objects. For example, the texture filter units 528 are configured to perform one or more magnification operations, anti-aliasing operations, or both to filter a texture.

Additionally, to help perform instructions for one or more workgroups, AU 500 includes acceleration circuitry 512. Such acceleration circuitry 512 includes hardware (e.g., fixed-function hardware) configured to execute one or more instructions for one or more workgroups. As an example, acceleration circuitry 512 includes one or more instances of fixed function hardware configured to encode frames, encode audio, decode frames, decode audio, display frames, output audio, perform matrix multiplication, or any combination thereof. To schedule instructions for execution on such hardware, scheduling circuitry 506 is configured to update one or more physical registers 532 of AU 500 associated with the hardware. In some cases, AU 500 includes one or more compute units 508 grouped into one or more shader engines 534. Referring to the example presented in FIG. 5, for example, AU 500 includes compute units 508-1 to 508-16 grouped in a first shader engine 534-1 and compute units 508-17 to 508-32 grouped in a second shader engine 534-2. Such shader engines 534, for example, are configured to execute one or more workgroups (e.g., one or more compute kernels) for an application and include one or more compute units 508, graphics processing hardware (e.g., primitive assemblers, rasterizers), one or more shared caches 510, render backends, or any combination thereof. Though the example presented in FIG. 5 shows AU 500 as including two shader engines (534-1, 534-2), in other implementations, AU 500 can include any number of shader engines (534-1, 534-2).

In conclusion, the examples employ inductors and/or T-coils for bandwidth extension, alongside eDTCs for power noise filtering for achieving high-speed operation with robust signal and power integrity. Strategic placement of these components ensures minimal layout area usage while maximizing performance. This approach is beneficial for high-speed systems. Moreover, by placing eDTCs between DQ pins in high-speed memory systems delivers multiple benefits, including enhanced power integrity, improved signal quality, optimized layout, and better overall system performance. Sharing these eDTCs across multiple DQ pins further optimizes the system by reducing layout area, minimizing component count, and providing efficient power and thermal management. This approach ensures that high-speed memory systems can operate reliably and efficiently, even as data rates and system complexity continue to increase.

In the preceding, reference is made to embodiments presented in this disclosure. However, the scope of the present disclosure is not limited to specific described embodiments. Instead, any combination of the described features and elements, whether related to different embodiments or not, is contemplated to implement and practice contemplated embodiments. Furthermore, although embodiments disclosed herein may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

As will be appreciated by one skilled in the art, the embodiments disclosed herein may be embodied as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium is any tangible medium that can contain, or store a program for use by or in connection with an instruction execution system, apparatus or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages, including an object oriented programming language such as Java, Smalltalk, C++ or the like and conventional procedural programming languages, such as the "C" programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present disclosure are described below with reference to flowchart illustrations and/or block diagrams of methods, apparatus (systems) and computer program products according to embodiments presented in this disclosure. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various examples of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the foregoing is directed to specific examples, other and further examples may be devised without departing from the basic scope thereof, and the scope thereof is determined by the claims that follow.

What is claimed is:

1. A chip package comprising:
an interposer including at least one embedded deep trench capacitor (eDTC) and at least one of an inductor, a T-coil, or a combination thereof; and
logic chips electrically connected to the interposer.

2. The chip package of claim 1, wherein the at least one eDTC is disposed in a different material layer of the interposer than the at least one of the inductor, the T-coil, or the combination thereof.

3. The chip package of claim 1, wherein the at least one of the inductor, the T-coil, or the combination thereof are configured to be disposed within a keep-out zone (KOZ).

4. The chip package of claim 1, wherein the at least one of the inductor, the T-coil, or the combination thereof are configured to be disposed in an upper layer of the interposer.

5. The chip package of claim 1, wherein each logic chip includes a transmitter, a receiver, and data in/out (DQ) pins.

6. The chip package of claim 5, wherein the DQ pins are configured to share a single eDTC.

7. The chip package of claim 5, wherein the DQ pins are configured to share multiple eDTCs.

8. The chip package of claim 5, wherein the at least one eDTC is disposed between the DQ pins.

9. The chip package of claim 5, wherein a first DQ pin on a first logic block shares an eDTC with a second DQ pin on a second logic block.

10. A chip package comprising:
an interposer including at least one embedded deep trench capacitor (eDTC); and
logic chips electrically connected to the interposer;
wherein each logic chip includes at least one data in/out (DQ) pin; and
wherein the at least one eDTC is shared by two or more DQ pins.

11. The chip package of claim 10, wherein the interposer includes at least one of an inductor, a T-coil, or a combination thereof.

12. The chip package of claim 11, wherein the at least one eDTC is disposed in a different material layer of the interposer than the at least one of the inductor, the T-coil, or the combination thereof.

13. The chip package of claim 10, wherein the DQ pins are configured to share a single eDTC.

14. The chip package of claim 10, wherein the DQ pins are configured to share multiple eDTCs.

15. The chip package of claim 10, wherein the at least one eDTC is disposed between the DQ pins.

16. The chip package of claim 10, wherein a first DQ pin on a first logic block shares an eDTC with a second DQ pin on a second logic block.

17. A method comprising:
forming at least one embedded deep trench capacitor (eDTC) and at least one of an inductor, a T-coil, or a combination thereof in an interposer; and
electrically connecting logic chips to the interposer, wherein the logic chips include data in/out (DQ) pins.

18. The method of claim 17, wherein the at least one of the inductor, the T-coil, or the combination thereof are configured to achieve high-speed operation of more than 10Gb/s per pin while maintaining power noise immunity.

19. The method of claim 17, wherein the DQ pins are configured to share a single eDTC.

20. The method of claim 17, wherein the at least one eDTC is disposed between the DQ pins.
